(19) United States
(12) Patent Application Publication
(10) Pub. No.: US 2025/0056981 A1
(43) Pub. Date: Feb. 13, 2025

(54) DISPLAY DEVICE

(71) Applicant: Samsung Display Co., LTD., Yongin-si (KR)

(72) Inventors: Seung Min LEE, Yongin-si (KR); Dong Jo KIM, Yongin-si (KR); Hyun KIM, Yongin-si (KR); Seong Geun WON, Yongin-si (KR); Je Won YOO, Yongin-si (KR); Dan Bi CHOI, Yongin-si (KR); Souk June HWANG, Yongin-si (KR)

(21) Appl. No.: 18/630,547

(22) Filed: Apr. 9, 2024

(30) Foreign Application Priority Data
Aug. 7, 2023 (KR) 10-2023-0102661

(51) Int. Cl. H10K 59/127; H10K 59/80; H10K 77/10; H10K 102/00

(52) U.S. Cl. CPC H10K 59/127; H10K 59/871; H10K 77/111; H10K 2102/311

(57) ABSTRACT

A display device includes a first substrate including a first surface and a second surface, which are opposite to each other, where the first substrate includes a rigid material, a second substrate disposed on the first surface of the first substrate, where the second substrate includes a flexible material, and a plurality of light-emitting elements disposed on the second substrate, where the first substrate further include first side surfaces disposed between the first and second surfaces, and first inclined surfaces disposed between the first surface and the first side surfaces, where the first side surfaces and the first inclined surfaces are at edges of the first substrate in a bending area where the second substrate is bent, and the display device further includes a filler disposed between a bottom surface of the second substrate and the first side surfaces of the first substrate, in the bending area.

This application claims priority to Korean Patent Application No. 10-2023-0102661, filed on Aug. 7, 2023, and all the benefits accruing therefrom under 35 U.S.C. § 119, the content of which in its entirety is herein incorporated by reference.

### BACKGROUND

### 1. Field

Embodiments of the disclosure relate to a display device.

### 2. Description of the Related Art

With the advancement of the information society, there is a growing demand for display devices, which are for displaying images, in various forms. Display devices may take the form of flat-panel display devices such as a liquid crystal display (LCD), a field-emission display (FED), a light-emitting display panel, etc.

Such a display device may include a display area, which is for displaying images and a non-display area, which is disposed around the display area, for example, arranged to surround the display area. The non-display area may function as dead space. There have been attempts to reduce the width of the dead space to enhance immersion in the display area and to improve the aesthetic appeal of the display device.

To reduce the width of the non-display area, a bending area may be formed between a pad area and the display area, and can be bent to position the pad area beneath a display panel. In this case, a flexible substrate that is bendable or foldable can be used. As the size of the substrate increases, a rigid substrate can also be further included to maintain the shape of the display device.

### SUMMARY

Embodiments of the disclosure provide a display device with the width of dead space minimized.

Embodiments of the disclosure also provide a display device capable of minimizing the external impact applied to a bending area.

However, Embodiments of the disclosure are not restricted to those set forth herein. The above and other features of embodiments of the disclosure will become more apparent to one of ordinary skill in the art to which the disclosure pertains by referencing the detailed description of the disclosure given below.

According to an embodiment of the disclosure, a display device includes a first substrate including a first surface and a second surface, which are opposite to each other, where the first substrate includes a rigid material, a second substrate disposed on the first surface of the first substrate, where the second substrate includes a flexible material, and a plurality of light-emitting elements disposed on the second substrate, where he first substrate further include first side surfaces disposed between the first and second surfaces, and first inclined surfaces disposed between the first surface and the first side surfaces, where the first side surfaces and the first inclined surfaces are at edges of the first substrate in a bending area where the second substrate is bent, and the display device further includes a filler disposed between a bottom surface of the second substrate and the first side surfaces of the first substrate, in the bending area. In an embodiment, the filler may have a hardness of Shore 70D or higher.

In an embodiment, the display device may further include a panel bottom cover disposed on the second surface of the first substrate, where the filler may be in contact with a side surface of the panel bottom cover.

In an embodiment, the display device may further include an adhesive member disposed on the panel bottom cover, on the second surface of the first substrate, where the filler may be in contact with a side surface of the adhesive member.

In an embodiment, the side surface of the panel bottom cover and the side surface of the adhesive member may be positioned on the same line.

In an embodiment, the filler may further include an air gap, and the air gap may be disposed within the filler.

In an embodiment, a shape of the air gap may correspond to a shape of the filler.

In an embodiment, the display device may further include a panel bottom cover disposed on the second surface of the first substrate, where the air gap may include first corresponding surfaces facing the first side surfaces, a second corresponding surface corresponding to the bottom surface of the second substrate, and a third corresponding surface facing the side surface of the panel bottom cover.

In an embodiment, the first corresponding surfaces may be inclined surfaces, and the second corresponding surface may be a curved surface.

In an embodiment, the filler may further include protrusions, and the protrusions may be disposed between the first inclined surfaces and the bottom surface of the second substrate.

In an embodiment, a horizontal length of the first inclined surfaces may be about 120 micrometers (μm).

In an embodiment, a vertical length of the first inclined surfaces may be less than a vertical length of the first side surfaces.

In an embodiment, ends where the first side surfaces meet the first inclined surfaces may be positioned closer to the second surface than to the first surface in a thickness direction.

In an embodiment, an internal angle formed between the first inclined surfaces and the second surface may be greater than or equal to about 165 degrees.

In an embodiment, an internal angle formed between the first inclined surfaces and the first surface may be greater than or equal to about 120 degrees.

According to an aspect of the disclosure, there is provided a display device including, a first substrate including a first surface and a second surface, which are opposite to each other, and first side surfaces, which are disposed between the first and second surfaces, where the first substrate includes a rigid material, a protective layer disposed on the first surface of the first substrate, a second substrate disposed on the protective layer, where the second substrate includes a flexible material, and a plurality of light-emitting elements disposed on the second substrate, where each of the first side surfaces is directly connected to the first surface, and the display device further includes a filler disposed between a bottom surface of the second substrate and the first side surfaces of the first substrate, in a bending area where the second substrate is bent.

In an embodiment, the filler may have a hardness of Shore 70D or higher.

In an embodiment, the filler may include an air gap, and the air gap may be disposed within the filler.

In an embodiment, a shape of the air gap may correspond to a shape of the filler.

In an embodiment, an adhesive force of the protective layer with respect to the first substrate may be greater than an adhesive force of the second substrate with respect to the first substrate.

According to embodiments of the disclosure, the width of dead space can be minimized.

In such embodiments, the external impact applied to a bending area can be reduced or minimized.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view of a display device according to an embodiment of the disclosure;

FIG. 2 is a plan view illustrating a display panel and driver integrated circuits (ICs) according to an embodiment of the disclosure;

FIG. 3 is a perspective view of a display device according to another embodiment of the disclosure;

FIG. 4 is a cross-sectional view of a display device according to an embodiment of the disclosure;

FIG. 5 is a cross-sectional view taken along line X1-X1′ of FIG. 1;

FIG. 6 is a cross-sectional view illustrating the display device of FIG. 5 in a bent state;

FIG. 7 is an enlarged cross-sectional view of area A of FIG. 5;

FIG. 8 is a cross-sectional view of a conventional display device;

FIG. 9 is a graph showing the level of stress applied to a circuit layer of the conventional display device based on the push displacement of a bending area of the conventional display device;

FIG. 10 is a graph showing the level of stress applied to a circuit layer of the display device of FIG. 1 or 3 based on the push displacement of a bending area of the display device of FIG. 1 or 3;

FIG. 11 is a cross-sectional view of a display device according to another embodiment of the disclosure;

FIG. 12 is a cross-sectional view of a display device according to another embodiment of the disclosure;

FIG. 13 is a cross-sectional view of a display device according to another embodiment of the disclosure;

FIG. 14 is a cross-sectional view of a display device according to another embodiment of the disclosure; and

FIG. 15 is a cross-sectional view illustrating the display device of FIG. 14 in a bent state.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. Like reference numerals refer to like elements throughout.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

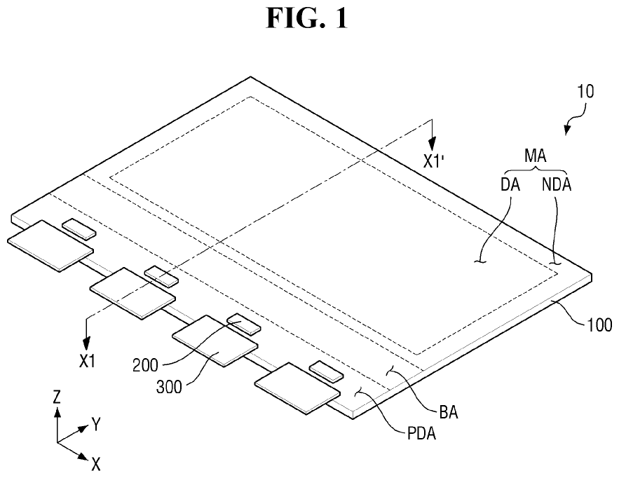

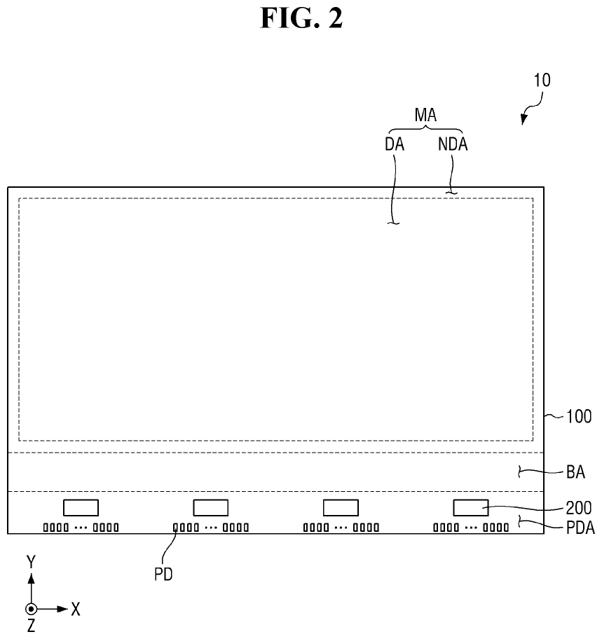

FIG. 1 is a perspective view of a display device according to an embodiment of the disclosure. FIG. 2 is a plan view illustrating a display panel and driver integrated circuits (ICs) according to an embodiment of the disclosure.

Referring to FIGS. 1 and 2, an embodiment of a display device 10, which is a device capable of displaying videos or still images, may be used to provide a display screen for an electronic device such as mobile phones, smartphones, tablet personal computers (PCs), smartwatches, watch phones, mobile communication terminals, electronic notepads, e-book readers, portable multimedia players (PMPs), navigational devices, ultra mobile PCs (UMPCs), as well as other various products such as televisions (TVs), laptops, monitors, advertising boards, and Internet of Things (IoT) devices.

The display device 10 may be a light-emitting display device such as an organic light-emitting display device using organic light-emitting diodes (OLEDs), a quantum-dot light-emitting display device including quantum-dot light-emitting layers, an inorganic light-emitting display device including an inorganic semiconductor, or a micro- or nano-light-emitting display device using micro- or nano-light-emitting diodes (LEDs), but the disclosure is not limited thereto.

The display device 10 may include a display panel 100, driver ICs 200, and circuit boards 300.

The display panel 100 may be formed to have a rectangular planar shape with a pair of long sides in a first direction (or an X-axis direction) and a pair of short sides in a second direction (or Y-axis direction) that intersects the first direction (or the X-axis direction). Corners where the long sides in the first direction (or the X-axis direction) meet the short sides in the second direction (or the Y-axis direction) may be right-angled or rounded with curvature. The planar shape of the display panel 100 is not particularly limited to rectangles, and the display panel 100 may also be formed in various other polygonal, circular, or elliptical shapes.

The first direction (or the X-axis direction) and the second direction (or the Y-axis direction) are illustrated as horizontal directions intersecting each other. For example, the first direction (or the X-axis direction) and the second direction (or the Y-axis direction) may be mutually orthogonal. A third direction (or a Z-axis direction) may be, for example, a vertically orthogonal direction intersecting the first direction (or the X-axis direction) and the second direction (or the Y-axis direction), or a thickness direction of the display panel 100. In this specification, the term “one side” or “first side” refers to the direction pointed to by the arrow representing each of the first, second, and third directions (or the X-, Y-, and Z-axis directions), and the term “the other side” or “second side” refers to an opposite direction, which is opposite to the one side corresponding thereto.

The display panel 100 may be formed to be flat, but the disclosure is not limited thereto. In an embodiment, for example, the display panel 100 may include curved portions, which are formed at the left and right ends of the display panel 100 and have a constant or varying curvature. In an embodiment, the display panel 100 may be flexibly formed to be bendable, foldable, or rollable.

The display panel 100 may include a main area MA, a bending area BA, and a pad area PDA. The main area MA may include a display area DA, which displays images, and a non-display area NDA, which is disposed around the display area DA.

The display area DA may occupy a major portion of the display panel 100. The display area DA may be disposed at the center of the display panel 100. Pixels each including multiple emission areas for displaying images may be disposed within the display area DA.

The non-display area NDA may be disposed adjacent to the display area DA. The non-display area NDA may be positioned outside the display area DA. The non-display area NDA may surround the display area DA. The non-display area NDA may correspond to the edges of the display panel 100.

The bending area BA may be disposed between the display area DA and the pad area PDA in the second direction (or the Y-axis direction). The bending area BA may extend in the first direction (or the X-axis direction). The bending area BA refers to a part of the display panel 100 that is bent downward beneath the display panel 100. In a state where the bending area BA is bent toward the bottom of the display panel 100, the driver ICs 200 and the circuit boards 300 may be positioned beneath the display panel 100.

The pad area PDA may correspond to the lower edge of the display panel 100. The pad area PDA may include display pads PD, and the driver pads PD may connect to the circuit boards 300 and first driver pads and second driver pads, which are connected to the driver ICs 200.

Within the pad area PDA, the display pads PD may be arranged to be connected with the circuit boards 300. The display pads PD may be disposed along one edge of the display panel 100. In an embodiment, for example, the display pads PD may be disposed along the lower edge of the display panel 100.

The driver ICs 200 may generate data voltages, power voltages, and scan timing signals. The driver ICs 200 may also output data voltages, power voltages, and scan timing signals.

The driver ICs 200 may be disposed on the display panel 100 in the pad area PDA. The driver ICs 200 may be positioned between the display pads PD and the display area DA in the non-display area NDA. In an embodiment, the driver ICs 200 may be attached to the non-display area NDA of the display panel 100 using a chip-on-glass (COG) method. Alternatively, the driver ICs 200 may be attached to the circuit boards 300 using a chip-on-plastic (COP) method.

The circuit boards 300 may be disposed on the display pads PD, which are arranged along one edge of the display panel 100. In an embodiment, the circuit boards 300 may be attached to the display pads PD using a conductive adhesive material such as an anisotropic conductive film or an anisotropic conductive adhesive. In such an embodiment, the circuit boards 300 may be electrically connected to signal lines of the display panel 100. The circuit boards 300 may be flexible films such as flexible printed circuit boards (FPCBs) or chip-on-films (COFs).

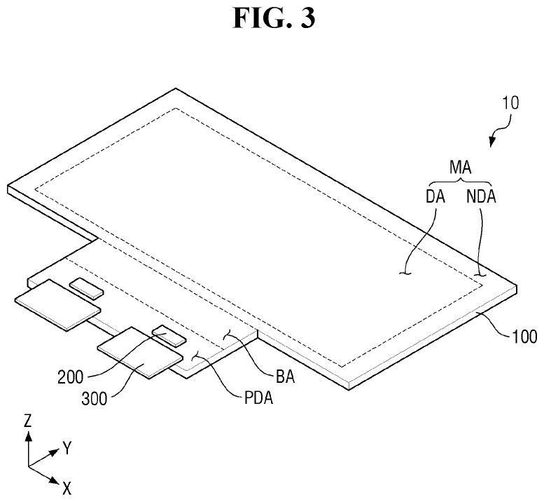

FIG. 3 is a perspective view of a display device according to another embodiment of the disclosure.

An embodiment of a display device 10 of FIG. 3 is substantially the same as the embodiment of the display device described above with reference to FIGS. 1 and 2 except for the shape of a display panel 100.

In an embodiment, referring to FIG. 3, the length, in the first direction (or the X-axis direction), of a main area MA of the display panel 100 may be greater than the lengths, in the first direction (or the X-axis direction), of a bending area BA and a pad area PDA of the display panel 100. The bending area BA and the pad area PDA may protrude from one of the sides of the main area MA.

The shape of the display panel 100 is not particularly limited and may vary depending on the type of the display device 10.

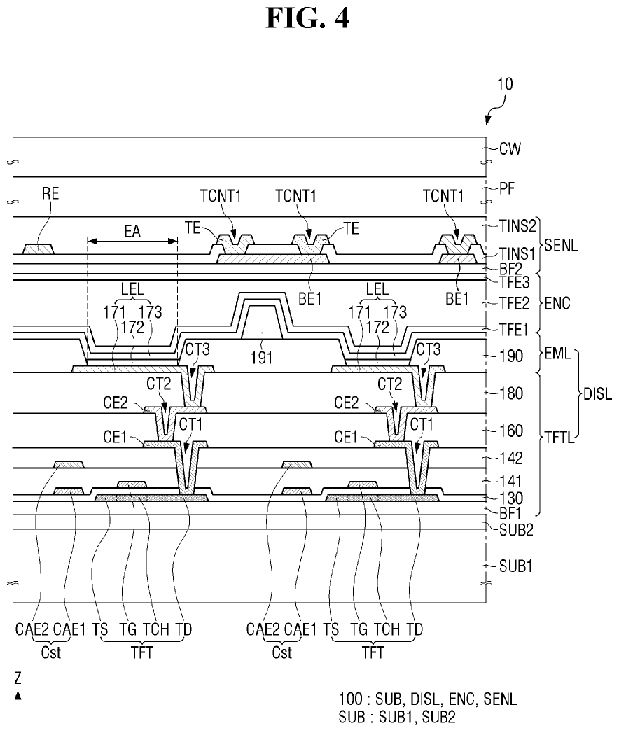

FIG. 4 is a cross-sectional view of a display device according to an embodiment of the disclosure. Particularly, the display device shown in FIG. 4 may correspond to the display device shown in FIG. 1 or 3.

Referring to FIG. 4, an embodiment of the display device 10 may include the display panel 100, a polarizing film PF, and a cover window CW.

In an embodiment, the display panel 100 may be an organic light-emitting display panel including light-emitting elements LEL, which include organic light-emitting layers, but the disclosure is not limited thereto. Alternatively, the display panel 100 may be a quantum-dot light-emitting display panel including quantum-dot light-emitting layers, an inorganic light-emitting display device including an inorganic semiconductor, or a micro- or nano-light-emitting display device using micro- or nano-LEDs. For convenience, embodiments where the display panel 100 is an organic light-emitting display panel will hereinafter be described in detail.

In an embodiment, the display panel 100 may include a substrate SUB, a display layer DISL, an encapsulation layer ENC, and a sensor electrode layer SENL.

The substrate SUB may include a first substrate SUB1, which include or is formed of a rigid material, and a second substrate SUB2, which include or is formed of a flexible material such as a polymer resin.

The first substrate SUB1 may include or be formed of a rigid material. In an embodiment, for example, the substrate SUB may include or be formed of glass. In an embodiment, for example, the substrate SUB may be formed of ultra-thin glass (UTG) with a thickness of about 500 micrometers (μm) or less.

The second substrate SUB2 may include or be formed of a flexible material. The second substrate SUB2 may include or be formed of a polymer resin and have a smaller thickness than the first substrate SUB1. In an embodiment, for example, the second substrate SUB2 may have a thickness of about 20 μm or less. The second substrate SUB2 may include or be formed of an organic material, such as an acrylic resin, epoxy resin, phenolic resin, polyamide resin, or polyimide resin. In an embodiment where the second substrate SUB2 is formed of a polymer resin, the second substrate SUB2 may also be referred to as a plastic substrate. In some embodiments, the second substrate SUB2 may have a multilayer structure.

The display layer DISL may include a thin-film transistor (TFT) layer TFTL (or a circuit layer), which includes a plurality of TFTs “TFT”, and a light-emitting element layer EML, which includes a plurality of light-emitting elements.

The TFT layer TFTL (or the circuit layer) may include a first buffer film BF1, the TFTs “TFT”, a gate insulating film 130, a first interlayer insulating film 141, capacitors Cst, a second interlayer insulating film 142, a first data metal layer, a first organic film 160, a second data metal layer, and a second organic film 180.

The first buffer film BF1 may be disposed on the substrate SUB. The first buffer film BF1 may include or be formed of an inorganic material, such as silicon nitride, silicon oxynitride, silicon oxide, titanium oxide, or aluminum oxide. Alternatively, the first buffer film BF1 may have a multilayer structure in which a silicon nitride layer, a silicon oxynitride layer, a silicon oxide layer, a titanium oxide layer, and/or an aluminum oxide layer are alternately stacked.

An active layer, which includes channel regions TCH, source regions TS, and drain regions TD of the TFTs “TFT”, may be disposed on the first buffer film BF1. The active layer may include or be formed of polycrystalline silicon, monocrystalline silicon, low-temperature polycrystalline silicon, amorphous silicon, or an oxide semiconductor material. In an embodiment where the active layer includes polycrystalline silicon or an oxide semiconductor material, the source regions TS and the drain regions TD in the active layer may be conductive regions doped with ions or impurities.

The gate insulating film 130 may be disposed on the active layer. The gate insulating film 130 may be formed as (or defined by) an inorganic film including or formed of an inorganic material, such as a silicon nitride, silicon oxynitride, silicon oxide, titanium oxide, or aluminum oxide film.

The first gate metal layer, which includes gate electrodes TG of the TFTs “TFT”, first capacitor electrodes CAE1 of the capacitors Cst, and scan lines, may be disposed on the gate insulating film 130. The gate electrodes TG of the TFTs “TFT” may overlap the channel regions TCH in the third direction (or the Z-axis direction). The first gate metal layer may be formed as a single layer or multilayer, each layer therein including molybdenum (Mo), aluminum (Al), chromium (Cr), gold (Au), titanium (Ti), nickel (Ni), neodymium (Nd), copper (Cu), or an alloy thereof.

The first interlayer insulating film 141 may be disposed on the first gate metal layer. The first interlayer insulating film 141 may be formed as an inorganic film including or formed of an inorganic material, such as a silicon nitride, silicon oxynitride, silicon oxide, titanium oxide, or aluminum oxide film. The first interlayer insulating film 141 may include multiple inorganic films.

The second gate metal layer, which includes second capacitor electrodes CAE2 of the capacitors Cst, may be disposed on the first interlayer insulating film 141. The second capacitor electrodes CAE2 may overlap the first capacitor electrodes CAE1 in the third direction (or the Z-axis direction). The capacitors Cst may be formed (or defined collectively) by the first capacitor electrodes CAE1, the second capacitor electrodes CAE2, and an inorganic insulating film acting as a dielectric layer arranged between the first capacitor electrodes CAE1 and the second capacitor electrodes CAE2. The second gate metal layer may be formed as a single layer or multilayer, each layer therein including Mo, Al, Cr, Au, Ti, Ni, Nd, Cu, or an alloy thereof.

The second interlayer insulating film 142 may be disposed on the second gate metal layer. The second interlayer insulating film 142 may be formed as an inorganic film including or formed of an inorganic material, such as a silicon nitride, silicon oxynitride, silicon oxide, titanium oxide, or aluminum oxide film. The second interlayer insulating film 142 may include multiple inorganic films.

The first data metal layer, which includes first connection electrodes CE1 and data lines, may be disposed on the second interlayer insulating film 142. The first connection electrode CE1 may be connected to the drain regions TD through first contact holes CT1 defined or formed in the gate insulating film 130, the first interlayer insulating film 141, and the second interlayer insulating film 142. The first data metal layer may be formed as a single layer or multilayer, each layer therein including Mo, Al, Cr, Au, Ti, Ni, Nd, Cu, or an alloy thereof.

The first organic film 160, which is for leveling or flattening the height difference caused by the TFTs “TFT”, may be disposed on the first connection electrodes CE1. The first organic film 160 may include or be formed of an organic material, such as an acryl resin, epoxy resin, phenolic resin, polyamide resin, or polyimide resin.

The second data metal layer, which includes the second connection electrodes CE2, may be disposed on the first organic film 160. The second data metal layer may be connected to the first connection electrodes CE1 through second contact holes CT2 that penetrate the first organic film 160. The second data metal layer may be formed as a single layer or multilayer, each layer therein including Mo, Al, Cr, Au, Ti, Ni, Nd, Cu, or an alloy thereof.

The second organic film 180 may be disposed on the second connection electrodes CE2. The second organic film 180 may include or be formed of an organic material, such as an acryl resin, epoxy resin, phenolic resin, polyamide resin, or polyimide resin.

In an embodiment, the second data metal layer, which includes the second connection electrodes CE2, and the second organic film 180 may be omitted.

The light-emitting element layer EML is disposed on the TFT layer TFTL. The light-emitting element layer EML may include the light-emitting elements LEL and a pixel-defining layer 190.

Each of the light-emitting elements LEL may include a pixel electrode 171, a light-emitting layer 172, and a common electrode 173. Each emission area EA represents an area where the pixel electrode 171, the light-emitting layer 172, and the common electrode 173 are sequentially stacked so that holes from the pixel electrode 171 and electrons from the common electrode 173 combine in the light-emitting layer 172 to emit light. In an embodiment, the pixel electrode 171 may be an anode, and the common electrode 173 may be a cathode.

A pixel electrode layer, which includes pixel electrodes 171, may be disposed on the second organic film 180. The pixel electrodes 171 may be connected to the second connection electrodes CE2 through third contact holes CT3 defined or formed in the second organic film 180. The pixel electrode layer may be formed as a single layer or multilayer of Mo, Al, Cr, Au, Ti, Ni, Nd, Cu, or an alloy thereof.

In an embodiment having a top emission structure that emits light in a direction from light-emitting layers 172 toward the common electrode 173, the pixel electrodes 171 may be formed as single layers of Mo, Ti, Cu, or Al, or as stacked structures of Ti/Al/Ti, indium tin oxide/aluminum/indium tin oxide (ITO/Al/ITO), a silver (Ag)-palladium (Pd)-copper (Cu) alloy, or ITO/APC/ITO to enhance reflectivity.

The pixel-defining layer 190 defines emission areas EA of the pixels. In an embodiment, the pixel-defining layer 190 may be disposed on the second organic film 180 to expose some portions of the pixel electrodes 171. The pixel-defining layer 190 may also cover the edges of the pixel electrodes 171. The pixel-defining layer 190 may be disposed within the third contact holes CT3. That is, the third contact holes CT3 may be filled with the pixel-defining layer 190. The pixel-defining layer 190 may be formed of or using an organic material, such as an acryl resin, epoxy resin, phenolic resin, polyamide resin, or polyimide resin.

Spacers 191 may be disposed on the pixel-defining layer 190. The spacers 191 may serve to support a mask during the fabrication of the light-emitting layers 172. The spacers 191 may include or be formed of an organic material, such as an acryl resin, epoxy resin, phenolic resin, polyamide resin, or polyimide resin.

The light-emitting layers 172 are disposed on the pixel electrodes 171. The light-emitting layers 172 may include an organic material and may thereby emit a particular color of light. In an embodiment, for example, the light-emitting layers 172 may include hole transport layers, organic material layers, and electron transport layers. Each of the organic material layers may include a host and a dopant. Each of the organic material layers may include a material that emits a particular color of light and may be formed using a phosphorescent or fluorescent material.

The common electrode 173 is disposed on the light-emitting layers 172. The common electrode 173 may be formed to cover the light-emitting layers 172. The common electrode 173 may serve as a common layer formed across the emission areas EA. A capping layer may be disposed on the common electrode 173.

In an embodiment having the top emission structure, the common electrode 173 may be formed using a transparent conductive oxide (TCO), such as ITO or indium zinc oxide (IZO), which allows light to pass through, or a semi-transmissive conductive material, such as magnesium (Mg), Ag, or an alloy thereof. In an embodiment where the common electrode 173 is formed of a semi-transmissive conductive material, the emission efficiency of the light-emitting elements LEL can be enhanced due to the presence of micro cavities.

The encapsulation layer ENC may be disposed on the light-emitting element layer EML. The encapsulation layer ENC may include at least one inorganic film to prevent the penetration of oxygen or moisture into the light-emitting element layer EML. The encapsulation layer ENC may also include at least one organic film to protect the light-emitting element layer EML from contaminants such as dust. In an embodiment, for example, the encapsulation layer ENC may include a first inorganic encapsulation film TFE1, an organic encapsulation film TFE2, and a second inorganic encapsulation film TFE3.

The first inorganic encapsulation film TFE1 may be disposed on the common electrode 173, the organic encapsulation film TFE2 may be disposed on the first inorganic encapsulation film TFE1, and the second inorganic encapsulation film TFE3 may be disposed on the organic encapsulation film TFE2. The first and second inorganic encapsulation films TFE1 and TFE3 may be formed as multilayer in which one or more inorganic films including an inorganic material, such as silicon nitride, silicon oxynitride, silicon oxide, titanium oxide, and/or aluminum oxide, are alternately stacked. The organic encapsulation film TFE2 may include or be formed of an organic material, such as an acryl resin, epoxy resin, phenolic resin, polyamide resin, or polyimide resin.

The sensor electrode layer SENL may be positioned on the encapsulation layer ENC. The sensor electrode layer SENL may include a second buffer film BF2, first connectors BE1, a first sensor insulating film TINS1, sensor electrodes (TE and RE), and a second sensor insulating film TINS2.

The second buffer film BF2 may be disposed on the encapsulation layer ENC. The second buffer film BF2 may include at least one inorganic film. In an embodiment, for example, the second buffer film BF2 may be formed as a multilayer in which one or more inorganic films including an inorganic material, such as silicon nitride, silicon oxynitride, silicon oxide, titanium oxide, and/or aluminum oxide, are alternately stacked. Alternatively, the second buffer film BF2 may be omitted.

The first connectors BE1 may be disposed on the second buffer film BF2. The first connectors BE1 may be formed as single layers of Mo, Ti, Cu, or Al or as stacked structures of Ti/Al/Ti, ITO/Al/ITO, an APC alloy, or ITO/APC/ITO.

The first sensor insulating film TINS1 may be disposed on the first connectors BE1. The first sensor insulating film TINS1 may be formed as an inorganic film including an inorganic material, such as a silicon nitride, silicon oxynitride, silicon oxide, titanium oxide, and/or aluminum oxide.

The sensor electrodes (TE and RE), i.e., driving electrodes TE and sensing electrodes RE, may be disposed on the first sensor insulating film TINS1. In an embodiment, dummy patterns may be disposed on the first sensor insulating film TINS1. The driving electrodes TE, the sensing electrodes RE, and the dummy patterns may not overlap the emission areas EA in the third direction (the Z-axis direction). The driving electrodes TE, the sensing electrodes RE, and the dummy patterns may be formed as single layer including Mo, Ti, Cu, or Al or as stacked structures of Ti/Al/Ti, ITO/Al/ITO, an APC alloy, or ITO/APC/ITO.

The second sensor insulating film TINS2 may be disposed on the driving electrodes TE, the sensing electrodes RE, and the dummy patterns. The second sensor insulating film TINS2 may include at least one selected from an inorganic film and an organic film. The inorganic film may be a film including silicon nitride, silicon oxynitride, silicon oxide, titanium oxide, or aluminum oxide. The organic film may be a film including acrylic resin, epoxy resin, phenolic resin, polyamide resin, or polyimide resin.

The polarizing film PF may be disposed on the sensor electrode layer SENL. The polarizing film PF may be disposed on the display panel 100 to reduce external glare. The polarizing film PF may include a first base member, a linear polarizer, a phase delay film such as a quarter-wave (24) plate, and a second base member. The first base member, the phase delay film, the linear polarizer, and second base member of the polarizing film PF may be sequentially stacked on the display panel 100.

The cover window CW may be disposed on the polarizing film PF. The cover window CW may be attached to the polarizing film PF using a transparent adhesive material, such as an optically clear adhesive (OCA) film.

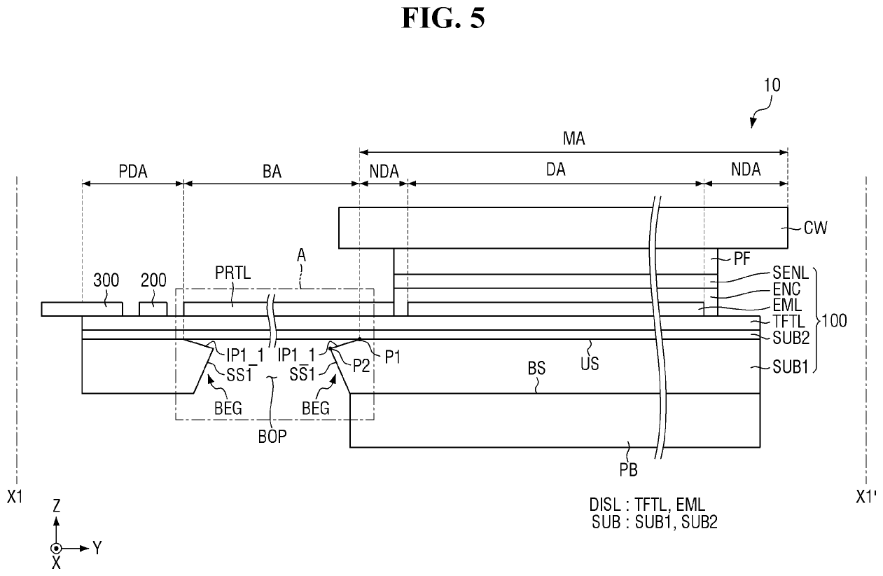

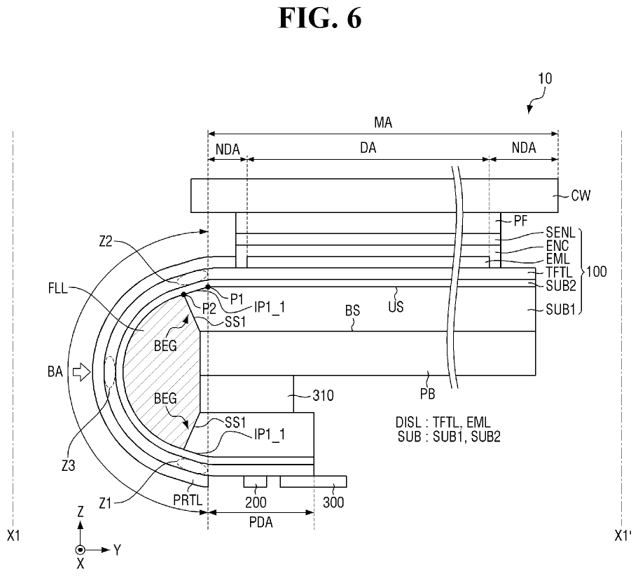

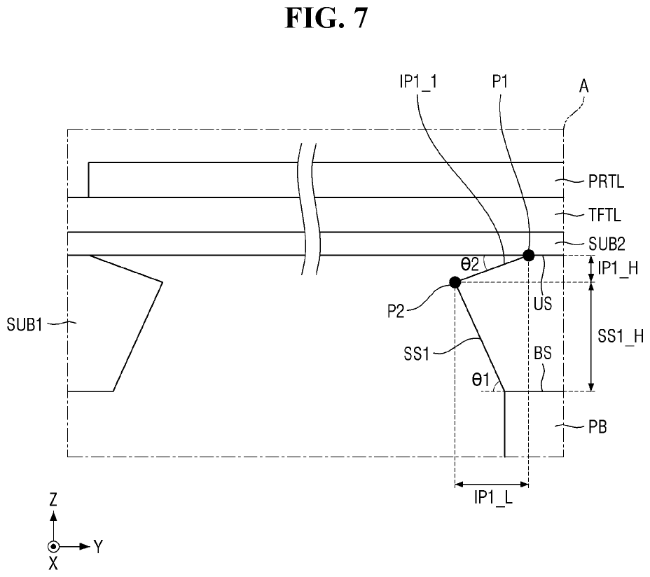

FIG. 5 is a cross-sectional view taken along line X1-X1′ of FIG. 1. FIG. 6 is a cross-sectional view illustrating the display device of FIG. 5 in a bent state. FIG. 7 is an enlarged cross-sectional view of area A of FIG. 5.

Referring to FIGS. 5 through 7, an embodiment of the display device 10 may further include a protective film PRTL, a panel bottom cover PB, and a filler FLL, in addition to the display panel 100, the polarizing film PF, the cover window CW, the driver ICs 200, and the circuit boards 300. The display panel 100 may include the substrate SUB, the display layer DISL, the encapsulation layer ENC, and the sensor electrode layer SENL.

In such an embodiment, the display layer DISL, the encapsulation layer ENC, the sensor electrode layer SENL, the polarizing film PF, and the cover window CW are substantially the same as those described above, and thus, any repetitive detailed descriptions thereof will be omitted.

The substrate SUB may include the first substrate SUB1, which includes a rigid material, and the second substrate SUB2, which includes a flexible material such as a polymer resin. The first substrate SUB1 may not overlap an entire portion of the bending area BA, that is, at least a portion of the bending area BA may not overlap the first substrate SUB1 in the third direction (or the Z-axis direction). In an embodiment, for example, the first substrate SUB1 may define an opening BOP, which exposes a portion of the second substrate SUB2 corresponding to the bending area BA. Thus, as the rigid material of the first substrate SUB1 is not present in the bending area BA, the substrate SUB can be easily bent, as illustrated in FIG. 6.

The protective film PRTL may be disposed on the TFT layer TFTL to overlap the bending area BA, that is, a portion of the TFT layer TFTL corresponding to the bending area BA is covered by the protective film PRTL. The protective film PRTL may be a layer for protecting a part of the TFT layer TFTL exposed in the bending area BA. The protective film PRTL may include or be formed of an organic material such as an acrylic resin, epoxy resin, phenolic resin, polyamide resin, or polyimide resin.

The panel bottom cover PB may be disposed on a second surface of the substrate SUB of the display panel 100. The second surface of the substrate SUB may be opposite to a first surface of the substrate SUB. In an embodiment, for example, the panel bottom cover PB may be disposed on a bottom surface BS of the substrate SUB. The panel bottom cover PB may be attached to the second surface of the substrate SUB of the display panel 100 through an adhesive material. The adhesive material may be a pressure-sensitive adhesive (PSA).

The panel bottom cover PB may include at least one selected from a light-absorbing material for absorbing incoming light from the outside, a buffer material for absorbing impacts from the outside, and a heat-dissipating material for efficiently releasing heat from the display panel 100.

The driver ICs 200 and the circuit boards 300 may bend downward beneath the display panel 100, as illustrated in FIG. 6. The circuit boards 300 may be attached to the bottom surface of the panel bottom cover PB using an adhesive member 310.

The adhesive member 310 may be a PSA. The adhesive member 310 may be positioned between a portion of the first substrate SUB1 disposed within the main area MA and a portion of the first substrate SUB1 disposed within the pad area PDA when the display device 10 is in a bent state. The adhesive member 310 may also be disposed beneath the panel bottom cover PB.

In some embodiments, the end of the adhesive member 310 adjacent to the bending area BA may be disposed on a same line or plane as the end of the panel bottom cover PB adjacent to the bending area BA. In an embodiment, for example, the ends of the adhesive member 310 and the panel bottom cover PB may be aligned with each other or collectively define a substantially continuous flat surface.

In an embodiment, as shown in FIG. 7, the first substrate SUB1 may include a top surface US, the bottom surface BS, first side surfaces SS1, and first inclined surfaces IP1_1. The top surface US of the first substrate SUB1 may be the surface of the first substrate SUB1 on the side of (or facing) the third direction (or the Z-axis direction), and the bottom surface BS of the first substrate SUB1 may be the surface of the first substrate SUB1 on the side of (or facing) the opposite direction of the third direction (or the Z-axis direction).

The first side surfaces SS1 may be positioned at edges BEG of (or adjacent to) the bending area BA. The edges BEG of the bending area BA may refer to the edges formed by etching a portion of the first substrate SUB1 in the bending area BA.

The first side surfaces SS1 may be positioned between the top surface US and the bottom surface BS. The first side surfaces SS1 may be located at the edges BEG of the bending area BA. The first side surfaces SS1 may be inclined. In an embodiment, for example, the angle formed between the first side surfaces SS1 and the top surface US may be an acute angle, while the angle between the first side surfaces SS1 and the bottom surface BS may be an obtuse angle.

The first side surfaces SS1 formed at the edges BEG of the bending area BA may be inclined surfaces. In an embodiment, for example, as illustrated in FIG. 7, a first angle θ1, which is an exterior angle formed between the bottom surface BS and the first side surfaces SS1 of the first substrate SUB1, may be less than about 60 degrees. That is, an internal angle between the bottom surface BS and the first side surfaces SS1 of the first substrate SUB1 (i.e., 180°−θ1) may be greater than or equal to about 120 degrees.

The first side surfaces SS1 may be formed during the fabrication of the display device 10 by attaching a protective film and etching a portion of the first substrate SUB1 in the bending area BA. In an embodiment, for example, the protective film may be attached to the entire first substrate SUB1 except for the bending area BA, allowing only the portion of the first substrate SUB1 located in the bending area BA to be partially etched first. Due to the isotropic characteristics of a wet etching process, the portion of the first substrate SUB1 in the bending area BA may become inclined. In such an embodiment, after the portion of the first substrate SUB1 in the bending area BA is partially etched to a certain thickness, the protective film may be removed, and remaining part of the portion of the first substrate SUB1 in the bending area BA may be completely etched. Accordingly, in such an embodiment, the thickness of the first substrate SUB1 can be reduced, and at the same time, the opening BOP, which exposes a portion of the second substrate SUB2 in the bending area BA, can be formed.

The first inclined surfaces IP1_1 may be positioned between the top surface US and the first side surfaces SS1. The first inclined surfaces IP1_1 may be undercuts formed between the first and second substrates SUB1 and SUB2. The first inclined surfaces IP1_1 may be formed due to an over-etching, where the etchant penetrates the interface between the first and second substrates SUB1 and SUB2 during the etching of the first substrate SUB1 as performed during the fabrication of the display device 10.

In an embodiment, as illustrated in FIG. 7, a length IP1_L of the first inclined surfaces IP1_1 in the second direction (or the Y-axis direction) may be approximately 120 μm. The length IP1_L of the first inclined surfaces IP1_1 may refer to the distance from ends P2 of the edges BEG to boundaries P1 where the first inclined surfaces IP1_1 meet the top surface US of the first substrate SUB1. An angle θ2, which is an exterior angle formed between the top surface US and the first inclined surfaces IP1_1 of the first substrate SUB1, may be less than about 15 degrees. That is, an internal angle between the top surface US and the first inclined surfaces IP1_1 of the first substrate SUB1 (i.e., 180°−θ2) may be greater than or equal to about 165 degrees.

The ends P2 of the edges BEG may be positioned closer to the top surface US than to the bottom surface BS. In an embodiment, for example, the length (or height) IP1_H of the first inclined surfaces IP1_1 in the third direction (or the Z-axis direction) may be smaller than a length (or height) SS1_H of the first side surfaces SS1 in the third direction (or the Z-axis direction).

If an over-etching occurs during the fabrication of the display device 10, causing the lengths IP1_L and IP1_H of the first inclined surfaces IP1_1 to become excessively large, the first inclined surfaces IP1_1 may overlap the display area DA. However, if the first inclined surfaces IP1_1 overlap the display area DA, cracks may occur in the TFT layer TFTL during the bending of the display device 10.

In an embodiment, the ends P2 of the edges BEG is positioned to be closer to the top surface US than to the bottom surface BS, it is possible to adjust the size of the first inclined surfaces IP1_1 and effectively prevent cracks from occurring in the TFT layer TFTL.

In an embodiment, as shown in FIG. 6, the display device 10 may include the filler FLL. The filler FLL may be disposed within (or in a space defined by) the opening BOP of the first substrate SUB1. In an embodiment, for example, the filler FLL may be surrounded by (or in contact with) the bottom surface of the second substrate SUB2, the first side surfaces SS1 of the first substrate SUB1, and a side surface of the panel bottom cover PB and a side surface of the adhesive member 310.

The filler FLL may reduce or minimize external impacts transmitted to the TFT layer TFTL near the bending area BA. The hardness of the filler FLL may be Shore 70D or higher, that is, the filler FLL may have 70 in Shore D hardness scale. Here, Shore D hardness may be measured through a Shore Hardness gauge known in the art. By ensuring the hardness of the filler FLL to be Shore 70D or higher, the display device 10 may achieve an improvement in external impact resistance. In some embodiments, the filler FLL may include silicone, but the disclosure is not limited thereto.

The display device 10 having the filler FLL with a hardness of shore 70D or higher will hereinafter be described in comparison with a conventional display device 10′ with no filler FLL.

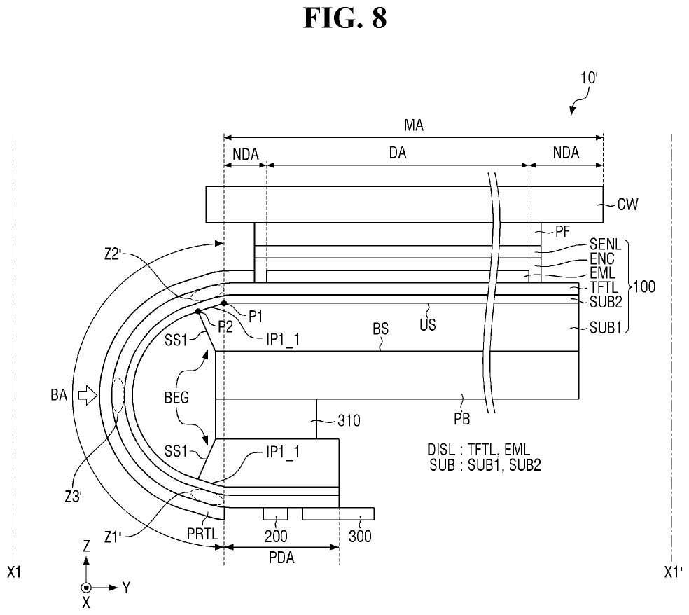

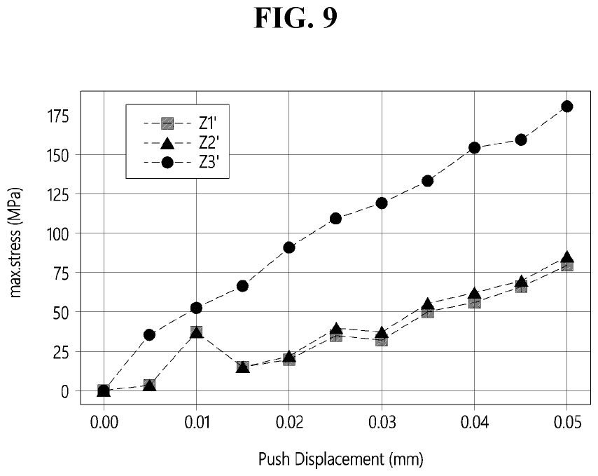

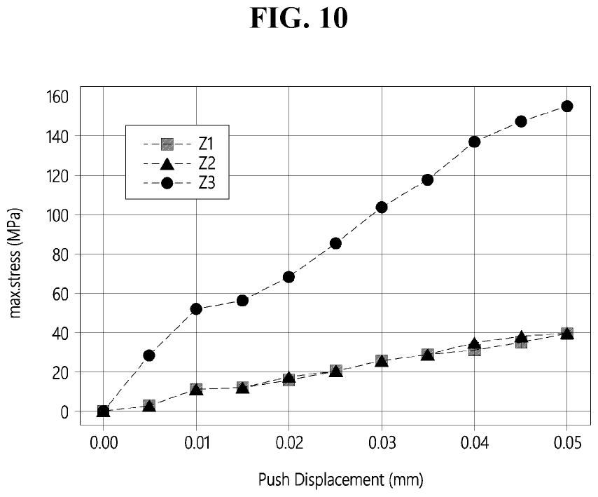

FIG. 8 is a cross-sectional view of a conventional display device 10′. FIG. 9 is a graph showing the level of stress applied to the circuit layer of the conventional display device 10′ based on the push displacement of a bending area BA of the conventional display device 10′. FIG. 10 is a graph showing the level of stress applied to the circuit layer of the display device 10 based on the push displacement of the bending area BA of an embodiment of the display device 10 according to the disclosure.

Referring to FIGS. 8 through 10 and further to FIGS. 5 through 7, in both the display device 10 and the conventional display device 10′, stress can be exerted on the TFT layer TFTL (or TFTL′) due to impacts from the outside of the bending area BA.

As illustrated in FIG. 6, in an embodiment of the display device 10, the TFT layer TFTL may include a first zone Z1 and a second zone Z2, which are positioned on each of the first inclined surfaces IP1_1, and a third zone Z3, which is positioned at the center of the bending area BA.

Referring to FIG. 8, in the conventional display device 10′, the TFT layer TFTL′ may include a first zone Z1′ and a second zone Z2′, which are positioned on each of first inclined surfaces IP1_1, and a third zone Z3′, which is positioned at the center of the bending area BA.

FIG. 9 illustrates the variation of the maximum stress levels applied to the first, second, and third zones Z1′, Z2′, and Z3′ according to the push displacement in the bending area BA of the conventional display device 10′. FIG. 10 illustrates the variation of the maximum stress levels applied to the first, second, and third zones Z1, Z2, and Z3 according to the push displacement in the bending area BA of the display device 10.

Referring to FIG. 9, for the conventional display device 10′, when the push displacement is 0.05 millimeter (mm), the maximum stress level for the third zone Z3′ is approximately 175 megapascals (MPa) or greater. On the other hand, referring to FIG. 10, for an embodiment of the display device 10, when the push displacement is 0.05 mm, the maximum stress level for the third zone Z3 is within approximately 160 MPa.

Furthermore, for the conventional display device 10′, when the push displacement is 0.01 mm, the maximum stress levels for the first and second zones Z1′ and Z2′ are approximately 40 MPa or greater. On the other hand, for an embodiment of the display device 10, when the push displacement is 0.01 mm, the maximum stress levels for the first and second zones Z1 and Z2 are within approximately 15 MPa.

Moreover, for the entire range of push displacements, the maximum stress levels for the first, second, and third zones Z1, Z2, and Z3 of the display device 10 are lower than the maximum stress levels for the first, second, and third zones Z1′, Z2′, and Z3′ of the conventional display device 10′.

Accordingly, it would be understood that the display device 10 can reduce or minimize the external impacts applied to the bending area BA by utilizing the filler FLL with a hardness of Shore 70D or higher as described herein.

Other embodiments of the disclosure will hereinafter be described, focusing on the different features from the embodiments described above. The same or like reference numerals are employed for the same or like components in the specification and the drawings, and any repetitive detailed description thereof will be omitted.

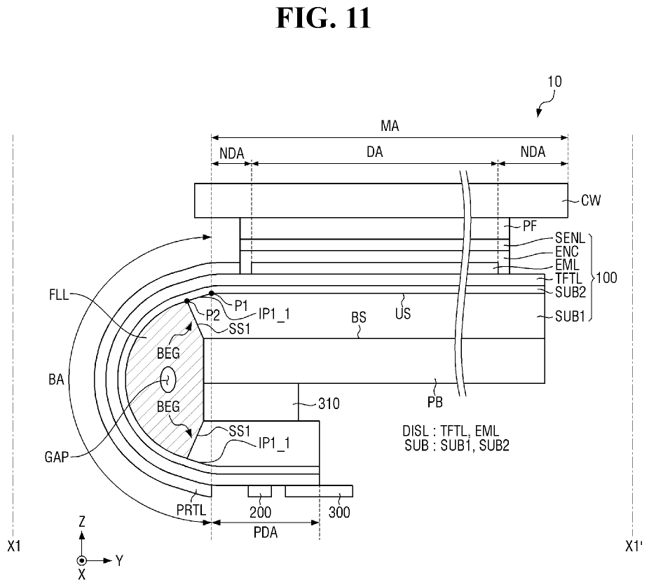

FIG. 11 is a cross-sectional view of a display device according to another embodiment of the disclosure.

A display device 10 of FIG. 11 is substantially the same as the display device 10 of FIG. 6 except for an air gap GAP defined in a filler FLL.

In an embodiment, as shown in FIG. 11, a filler FLL may include the air gap GAP defined therein. The air gap GAP may refer to an empty space not filled with the filler FLL.

The air gap GAP may be defined or disposed within the filler FLL. The air gap GAP may be positioned at the center of the filler FLL, but the disclosure is not limited thereto. In an embodiment, the air gap GAP may have an elliptical shape as shown in FIG. 11, but the disclosure is not limited thereto.

In an embodiment, the display device 10 can further reduce the maximum stress level for a bending area for a push displacement by incorporating the air gap GAP. In an embodiment, for example, when the push displacement is 0.05 mm, the maximum stress level for a third zone Z3 of the display device 10 may be within approximately 150 MPa.

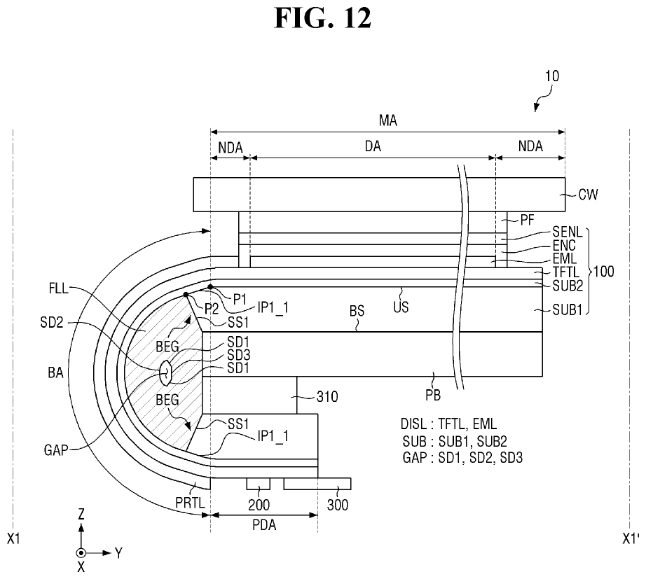

FIG. 12 is a cross-sectional view of a display device according to another embodiment of the disclosure.

A display device 10 of FIG. 12 is substantially the same as the display device 10 of FIG. 11 except for the shape of an air gap GAP.

In an embodiment, as shown in FIG. 12, the shape of the air gap GAP may correspond to (or be similar to) the shape of a filler FLL. Here, the correspondence between the shape of the air gap GAP and the shape of the filler FLL means that the air gap GAP has a same shape as the outer contour of the filler FLL, but has different dimensions from the filler FLL.

In an embodiment, for example, the air gap GAP may include first corresponding surfaces SD1, a second corresponding surface SD2, and a third corresponding surface SD3.

The first corresponding surfaces SD1 may face first side surfaces SS1. The second corresponding surface SD2 may face the bottom surface of a second substrate SUB2. The third corresponding surface SD3 may face the side surfaces of a panel bottom cover PB and an adhesive member 310.

In some embodiments, the first corresponding surfaces SD1 may be inclined surfaces along the first side surfaces SS1. The second corresponding surface SD2 may be curved along a bending area BA. The third corresponding surface SD3 may be a vertical surface extending along the side surfaces of the panel bottom cover PB and the adhesive member 310.

In an embodiment, external forces from particular directions can be evenly distributed to all directions by ensuring the shape of the air gap GAP corresponding to the shape of the filler FLL. Accordingly, in such an embodiment, the stress applied to a TFT layer TFTL can be further minimized.

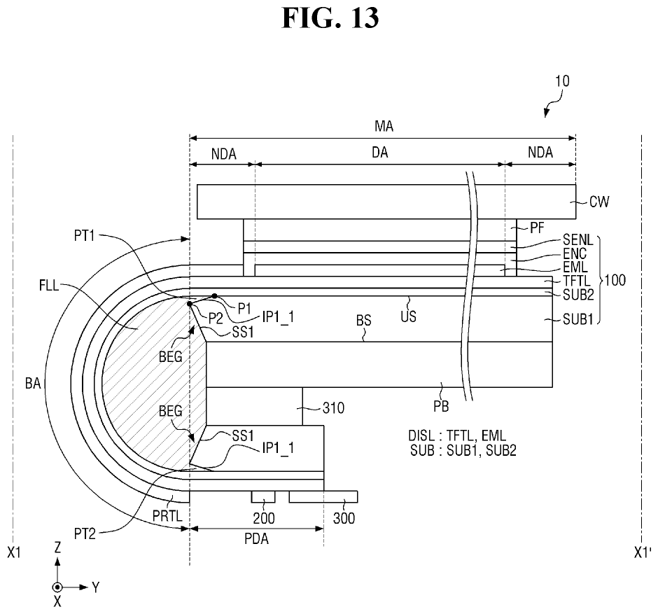

FIG. 13 is a cross-sectional view of a display device according to another embodiment of the disclosure.

A display device 10 of FIG. 13 is substantially the same as the embodiments described above except that a filler FLL is disposed even between a second substrate SUB2 and first inclined surfaces IP1_1.

In an embodiment, as shown in FIG. 13, the filler FLL may be disposed between the second substrate SUB2 and the first inclined surfaces IP1_1.

In an embodiment, for example, the filler FLL may include a first protrusion PT1, which is positioned in a main area MA, and a second protrusion PT2, which is positioned in a pad area PDA. The first and second protrusions PT1 and PT2 may be disposed between the second substrate SUB2 and the first inclined surfaces IP1_1. In such an embodiment, the first and second protrusions PT1 and PT2 of the filler FLL may be disposed within the undercuts formed between a first substrate SUB1 and the second substrate SUB2.

In an embodiment, potential lifting of the second substrate SUB2 can be effectively prevented by filling the undercuts, formed between the first and second substrates SUB1 and SUB2, with the filler FLL. In such an embodiment, any harm inflicted on a TFT layer TFTL by tips formed at ends P2 of edges BEG of a bending area BA can be minimized.

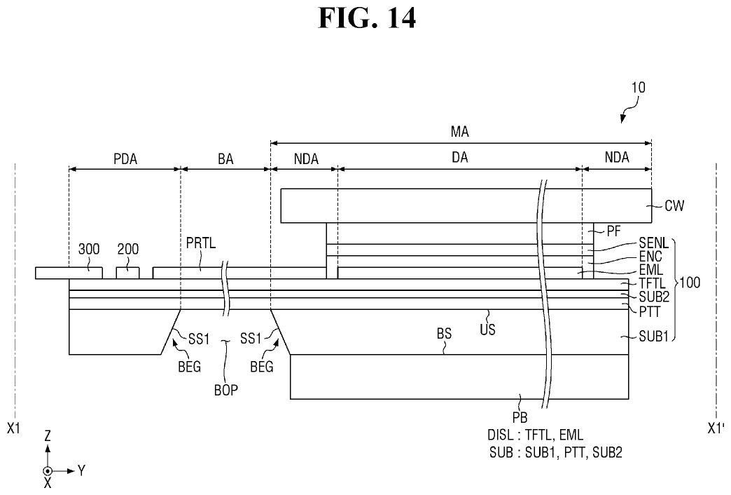

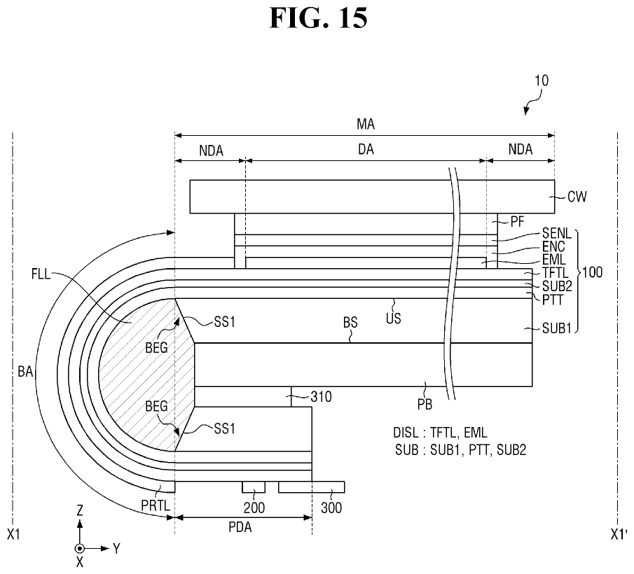

FIG. 14 is a cross-sectional view of a display device according to another embodiment of the disclosure. FIG. 15 is a cross-sectional view illustrating the display device of FIG. 14 in a bent state.

A display device 10 of FIGS. 14 and 15 is substantially the same as the embodiments described above except that the display device 10 further includes a protective layer PTT.

In an embodiment, as shown in FIG. 14, the display device 10 may further include the protective layer PTT.

A substrate SUB of the display device 10 may include a first substrate SUB1, the protective layer PTT, which is disposed on the first substrate SUB1, and a second substrate SUB2, which is disposed on the protective layer PTT.

The first substrate SUB1 may define an opening BOP, which exposes the protective layer PTT. The second substrate SUB2 may be positioned on the protective layer PTT.

The protective layer PTT may be disposed between the first and second substrates SUB1 and SUB2. The protective layer PTT may have a thickness of approximately 0.1 μm or less. The protective layer PTT may include a material with a greater (higher or stronger) adhesive force with respect to the first substrate SUB1 than to the second substrate SUB2.

In some embodiments, the protective layer PTT may include silicon (Si). In an embodiment, for example, the protective layer PTT may include at least one selected from amorphous silicon (a-Si), silicon oxide (SiOₓ), silicon nitride (SiNₓ), and silicon oxynitride (SiOₓN_{y}).

The protective layer PTT can effectively prevent the first substrate SUB1 from being over-etched and can thereby prevent the formation of undercuts. That is, the formation of first inclined surfaces IP1_1 in the display device 10 can be effectively prevented. In an embodiment, for example, the adhesive force of the protective layer PTT with respect to the first substrate SUB1 may be greater (higher or stronger) than the adhesive force of the protective layer PTT with respect to the second substrate SUB2. In such an embodiment, during the fabrication of the display device 10, the reactivity of the protective layer PTT to an etchant may be lower than the reactivity of the second substrate SUB2 to the etchant. Accordingly, the formation of undercuts can be effectively prevented by minimizing the penetration of the etchant into the interface between the first substrate SUB1 and the protective layer PTT.

In such an embodiment, as the formation of undercuts at edges BEG of a bending area BA can be effectively prevented, damage to the edges BEG of the bending area BA and the lifting of the second substrate SUB2 can both be effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first substrate comprising a first surface and a second surface, which are opposite to each other in a thickness direction thereof, wherein the first substrate includes a rigid material;
a second substrate disposed on the first surface of the first substrate, wherein the second substrate includes a flexible material; and
a plurality of light-emitting elements disposed on the second substrate,
wherein,
wherein the first substrate further comprise:
first side surfaces disposed between the first and second surfaces; and
first inclined surfaces disposed between the first surface and the first side surfaces, wherein the first side surfaces and the first inclined surfaces are at edges of the first substrate in a bending area where the second substrate is bent, and
wherein the display device further comprises a filler disposed between a bottom surface of the second substrate and the first side surfaces of the first substrate, in the bending area.

2. The display device of claim 1, wherein the filler has a hardness of Shore 70D or higher.

3. The display device of claim 1, further comprising:
a panel bottom cover disposed on the second surface of the first substrate,
wherein the filler is in contact with a side surface of the panel bottom cover.

4. The display device of claim 3, further comprising:
an adhesive member disposed on the panel bottom cover, on the second surface of the first substrate,
wherein the filler is in contact with a side surface of the adhesive member.

5. The display device of claim 4, wherein the side surface of the panel bottom cover and the side surface of the adhesive member are positioned on a same plane.

6. The display device of claim 1, wherein the filler includes an air gap, and the air gap is disposed within the filler.

7. The display device of claim 6, wherein a shape of the air gap corresponds to a shape of the filler.

8. The display device of claim 7, further comprising:
a panel bottom cover disposed on the second surface of the first substrate,
wherein the air gap comprises:
first corresponding surfaces facing the first side surfaces;
a second corresponding surface corresponding to the bottom surface of the second substrate; and
a third corresponding surface facing the side surface of the panel bottom cover.

9. The display device of claim 8, wherein
the first corresponding surfaces are inclined surfaces, and
the second corresponding surface is a curved surface.

10. The display device of claim 1, wherein the filler further includes protrusions, and the protrusions are disposed between the first inclined surfaces and the bottom surface of the second substrate.

11. The display device of claim 1, wherein a horizontal length of the first inclined surfaces is about 120 micrometers.

12. The display device of claim 1, wherein a vertical length of the first inclined surfaces is less than a vertical length of the first side surfaces.

13. The display device of claim 12, wherein ends where the first side surfaces meet the first inclined surfaces are positioned closer to the second surface than to the first surface in a thickness direction.

14. The display device of claim 1, wherein an internal angle formed between the first inclined surfaces and the second surface is greater than or equal to about 165 degrees.

15. The display device of claim 1, wherein an internal angle formed between the first inclined surfaces and the first surface is greater than or equal to about 120 degrees.

16. A display device comprising:
a first substrate comprising:
a first surface and a second surface, which are opposite to each other; and
first side surfaces, which are disposed between the first and second surfaces, wherein the first substrate includes a rigid material;
a protective layer disposed on the first surface of the first substrate;
a second substrate disposed on the protective layer, wherein the second substrate includes a flexible material; and
a plurality of light-emitting elements disposed on the second substrate,
wherein
each of the first side surfaces is directly connected to the first surface, and
the display device further comprises a filler disposed between a bottom surface of the second substrate and the first side surfaces of the first substrate, in a bending area where the second substrate is bent.

17. The display device of claim 16, wherein the filler has a hardness of Shore 70D or higher.

18. The display device of claim 16, wherein the filler includes an air gap, and the air gap is disposed within the filler.

19. The display device of claim 18, wherein a shape of the air gap corresponds to a shape of the filler.

20. The display device of claim 16, wherein an adhesive force of the protective layer with respect to the first substrate is greater than an adhesive force of the second substrate with respect to the first substrate.
